(19) United States
(12) Patent Application Publication
(10) Pub. No.: US 2008/0034581 A1
(43) Pub. Date: Feb. 14, 2008

(54) Method for manufacturing printed circuit board

(75) Inventors: Seung-Hyun Ra, Seongnam-si (KR); Choon-Keun Lee, Suwon-si (KR); Sang-Moon Kee, Seoul (KR); Jae-Choon Cho, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/889,328

(22) Filed: Aug. 10, 2007

(30) Foreign Application Priority Data
Aug. 11, 2006 (KR) 10-2006-0076396

(51) Int. Cl. H05K 3/00

(52) U.S. Cl. 29/834; 29/829; 29/830; 29/846; 29/833

(57) ABSTRACT

A method for manufacturing a printed circuit board is disclosed. With a method for manufacturing a printed circuit board which includes loading an insulation substrate in which an align mark is formed, loading an imprinting mold in which a first align hole is perforated in correspondence with the align mark, aligning the insulation substrate and the imprinting mold by perceiving the align mark through the first align hole, and compressing the imprinting mold and the insulation substrate together such that the intaglio pattern is formed in correspondence with the raised pattern, it is possible is to use an existing optical system for an imprinting process in aligning an opaque imprinting mold and an insulation substrate, without installing expensive alignment instruments, and to manufacture several insulation substrates having circuit patterns by sequentially loading and aligning several imprinting molds and insulation substrates and compressing simultaneously.

### CROSS-REFERENCE TO RELATED APPLICATIONS

This application claims the benefit of Korean Patent Application No. 10-2006-0076396 filed with the Korean Intellectual Property Office on Aug. 11, 2006, the disclosure of which is incorporated herein by reference in its entirety.

### BACKGROUND

1. Technical Field

The present invention relates to a method for manufacturing a printed circuit board, more particularly to a method for manufacturing a printed circuit board using an imprinting method.

2. Description of the Related Art

With developments in the electronics industry, electronic parts, including cellular phones, are becoming smaller and being equipped with more functionality, creating a continuously increasing demand for smaller and higher-density printed circuit boards. At the same time, according to the trends of smaller and lighter electronic products, the printed circuit board is also becoming miniaturized, packaged, and endowed with finer patterns.

One technology for manufacturing fine circuit patterns that has been widely used until now is photolithography, which is a method of forming a pattern on a substrate laminated with a thin film of photoresist. However, the size of the patterns formed at this time is limited by an optical diffraction phenomenon, and the resolution is nearly proportional to the wavelength of the light beam used. Thus, the higher the level of integration of the semiconductor device, exposure of the shorter wavelength is required in order to form fine patterns. This, however, causes irregularities in the CD (critical dimensions) of the photoresist pattern, so that the circuit patterns formed using this photoresist pattern as a mask is made different from the circuit patterns first desired. Also, since the photoresist reacts with impurities generated during the process and becomes eroded, the photoresist pattern may be altered. These are some of the reasons why the method of manufacturing the printed circuit board using the imprinting method for forming fine circuit patterns is currently receiving attention.

The method of imprinting for forming the pattern is to form the required shape in the surface of a material having a high relative strength and then imprint the shape such as by stamping, or to make a mold with the desired shape and then apply a polymer material inside the mold to form the pattern.

That is, in a method for forming printed circuit patterns using imprinting, first, an imprinting mold in which a raised pattern corresponding to the desired circuit pattern is formed is pressed onto the insulation substrate, and second, an intaglio pattern corresponding to the raised pattern is formed in the insulation substrate, where the circuit pattern is formed on the insulation substrate when this intaglio pattern is charged with the conductive material. Therefore, in order to form the circuit pattern on the insulation substrate by forming the exact intaglio pattern on the insulation substrate, it is of critical importance that the insulation substrate and the imprinting mold be aligned exactly.

FIG. 1 is a drawing illustrating a method for aligning a film mask and substrate according to prior art. Referring to FIG. 1, a film mask 2, a substrate 4, an alignment mark 6 and a camera 8 are illustrated.

In the method of forming circuit patterns by conventional photolithography, the film mask 2 is stacked on the top of the substrate in order to form the photoresist thin film. To do so, exact aligning is required between the film mask 2 and the substrate 4, in order to form fine circuit patterns and via holes for conduction between the upper layer of the substrate and the lower layer of the substrate 4 in their exact locations.

Conventionally, an optical system has been used for the exact aligning between the substrate 4 and the film mask 2. That is, attempts were made to accurately align the film mask 2 and the substrate 4 while perceiving the alignment marks 6 through cameras 8 and moving the film mask 2 and the substrate 4.

However, in the method for aligning according to prior art, at least one of the two layers to be aligned should be transparent, to align the two layers by perceiving the alignment mark 6 of the other layer. Therefore, aligning is only possible in circumstances where either the imprinting mold or the substrate is transparent. However, both the imprinting mold and the insulation substrate are opaque, so that the method for aligning according to prior art cannot be used.

Also, in the method for aligning according to prior art, more than two layers cannot be aligned. Consequently, the manufacturing yield is low.

### SUMMARY

An aspect of the invention is to use an existing optical system, for an imprinting process involving an imprinting mold having a raised pattern and an insulation substrate having an intaglio pattern formed in correspondence with the raised pattern, in aligning an opaque imprinting mold and an insulation substrate, without installing expensive alignment instruments, and to manufacture several insulation substrates having circuit patterns by sequentially loading and aligning several imprinting molds and insulation substrates and compressing simultaneously.

One aspect of the claimed invention provides a method for manufacturing a printed circuit board by imprinting a raised pattern formed in an imprinting mold in correspondence with a circuit pattern onto an insulation substrate to form an intaglio pattern, and filling a conductive material into the intaglio pattern formed in the insulation substrate to form a printed circuit pattern. The method may include loading an insulation substrate in which an align mark is formed, loading an imprinting mold in which a first align hole is perforated in correspondence with the align mark, aligning the insulation substrate and the imprinting mold by perceiving the align mark through the first align hole, and compressing the imprinting mold and the insulation substrate together such that the intaglio pattern is formed in correspondence with the raised pattern.

In order to form intaglio patterns in a plurality of insulation substrates, the processes of loading an insulation substrate or an imprinting mold in which a second align mark is perforated, and aligning the insulation substrate or the imprinting mold by perceiving the align mark through the second align hole, may be repeatedly performed before compressing the imprinting molds and the insulation substrates together.

In the present disclosure, an imprinting mold refers to a mold frame in which a desired shape is formed in advance in the surface of a material having a high relative strength. A pattern may be formed by imprinting the mold, such as by stamping onto other material or by applying a polymer material in the mold. The imprinting mold is a concept encompassing the stamp and the tool foil, etc.

It is possible to raise the exactitude of alignment by forming a plurality of align marks in the insulation substrate.

After the imprinting mold and the insulation substrate are compressed together, such that the intaglio pattern is formed in correspondence with the raised pattern formed in the insulation substrate, the imprinting mold and the insulation substrate may be separated, and the printed circuit pattern may be formed by filling conductive material into the intaglio pattern.

Also, a method is provided in which the align mark is formed on the imprinting mold, instead of the insulation substrate. That is, a method for manufacturing a printed circuit board by imprinting a raised pattern formed in an imprinting mold in correspondence with a circuit pattern onto an insulation substrate to form an intaglio pattern, and filling a conductive material into the intaglio pattern formed in the insulation substrate to form a printed circuit pattern is provided, which may include loading an imprinting mold on which an align mark is formed, loading an insulation substrate in which a first align hole is perforated in correspondence with the align mark, aligning the insulation substrate and the imprinting mold by perceiving the align mark through the first align hole, and compressing the imprinting mold and the insulation substrate together such that the intaglio pattern is formed in correspondence with the raised pattern.

After the imprinting mold and the substrate are compressed together, such that the intaglio pattern is formed in correspondence with the raised pattern formed in the insulation substrate, the imprinting mold and the insulation substrate may be separated, and the printed circuit pattern may be formed by filling conductive material into the intaglio pattern.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a drawing illustrating a method for aligning a film mask and substrate according to prior art.

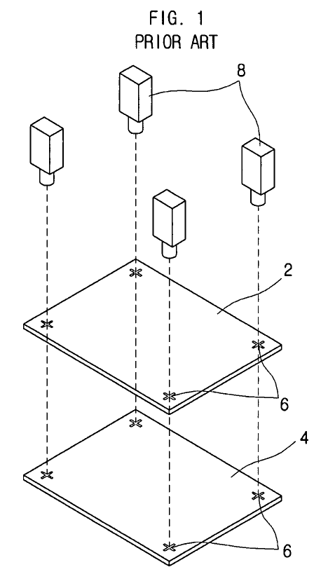

FIG. 2 is a perspective view illustrating a method for manufacturing a printed circuit board according to an embodiment of the present invention.

FIG. 3 is a side-elevational view illustrating a method for manufacturing a printed circuit board according to an embodiment of the present invention.

FIG. 4 is a side-elevational view illustrating a substrate in which a printed circuit pattern is formed according to an embodiment of the present invention.

FIG. 5 is a perspective view illustrating a method for manufacturing multiple printed circuit boards according to an embodiment of the present invention.

FIG. 6 is a side-elevational view illustrating a method for manufacturing a printed circuit board according to another embodiment of the present invention.

FIG. 7 is a side-elevational view illustrating a method for manufacturing multiple printed circuit boards according to another embodiment of the present invention.

FIG. 8 is a flowchart illustrating a method for manufacturing a printed circuit board according to an embodiment of the present invention.

FIG. 9 is a flowchart illustrating a method for manufacturing a printed circuit board according to another embodiment of the present invention.

### DETAILED DESCRIPTION

The method for manufacturing printed circuit board according to certain embodiments of the invention will be described below in more detail with reference to the accompanying drawings, in which those components are rendered the same reference number that are the same or are in correspondence, regardless of the figure number, and redundant explanations are omitted.

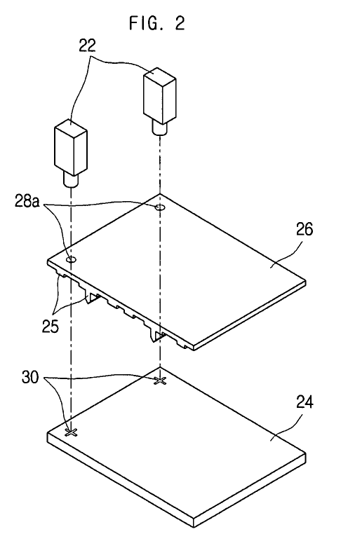

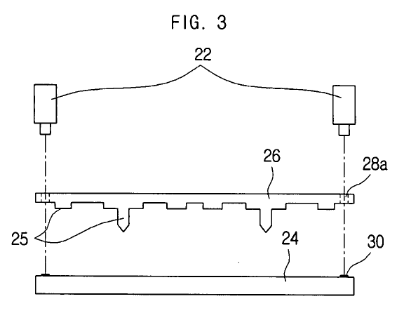

FIG. 2 is a perspective view illustrating a method for manufacturing a printed circuit board according to an embodiment of the present invention, and FIG. 3 is a side-elevational view illustrating a method for manufacturing a printed circuit board according to an embodiment of the present invention. Referring to FIG. 2 and FIG. 3, cameras 22, an insulation substrate 24, an imprinting mold 26, first align holes 28a, align marks 30, and a raised pattern 25 are illustrated.

In this embodiment, align marks 30 may be formed on a dummy area of the insulation substrate 24, and the insulation substrate 24 may be loaded such that a surface of the insulation substrate 24 in which to form the intaglio pattern corresponding to a circuit pattern faces a surface of the imprinting mold 26 having the raised pattern 25. The imprinting mold 26 having first align holes 28a in correspondence with the align marks 30 may be loaded such that a surface of the insulation substrate 24 in which to form the intaglio pattern faces a surface of the imprinting mold 26 having the raised pattern 25. Afterwards, the insulation substrate 24 and the imprinting mold 26 may be aligned by perceiving the align mark 30 through the first align holes 28a using a certain optical device (e.g. cameras 22, etc).

A plurality of align marks 30 may be formed in order to align the insulation substrate 24 and the imprinting mold 26 exactly. In this case, a plurality of align holes 28a may be perforated in correspondence with the plurality of align marks 30. The smaller the size of the align holes 28a, within the scope of allowing the cameras 22 to perceive the align marks 30 through the align holes 28a, the greater the exactitude of alignment. For example, in a PCB manufacturing process, a plurality of identical unit PCB's may be processed in one substrate at the same time, and then cut into unit PCB's afterwards. In the case of imprint processing a plurality of identical unit PCB's in an insulation substrate to form circuit patterns, the insulation substrate may be relatively large, so that the exactitude of alignment may be increased by thus forming the plurality of align marks and align holes.

After aligning the insulation substrate 24 and the imprinting mold 26, the insulation substrate 24 and the imprinting mold 26 may be compressed together to imprint the raised pattern 25 into the insulation substrate 24.

The first align holes 28a may be perforated using a drill by computer numerical control (CNC), in order that the align marks 30 may be perceived through the align holes 28a for more accurate aligning.

While in this embodiment, the insulation substrate 24 is loaded first and the imprinting mold 26 is loaded over the insulation substrate 24 afterwards such that a surface of the imprinting mold 26 having the raised pattern 25 faces the insulation substrate 24, in some cases, it is possible to first load the imprinting mold 26, and load the insulation substrate 24 over the imprinting mold 26 afterwards such that the surface of the imprinting mold 26 having the raised pattern 25 faces the insulation substrate 24, and then align the insulation mold 24 and the imprinting mold 26 by perceiving the align marks 30 formed onto the insulation substrate 24 through the first align holes 28a. That is, as long as the imprinting mold 26 and insulation substrate 24 are aligned in a pair such that a surface of the imprinting mold 26 having the raised pattern 25 faces a surface of the insulation substrate 24 to form the intaglio pattern, the loading order of the insulation substrate 24 and the imprinting mold 26 is not of great importance.

Metals, such as iron (Fe), nickel (Ni), platinum (Pt), and chrome (Cr), etc., or diamond, quartz, or polymers which are relatively strong in comparison with the insulation substrate 24, may be used as the material of the imprinting mold 26. Also, the raised pattern 25 formed in the imprinting mold 26 is not limited to certain shapes, and thus may be square shapes, V shapes, and U shapes, etc.

Moreover, a thermoplastic resin may be used as the material of the insulation substrate 24. However, the material of the insulation substrate 24 is not limited to thermoplastic resins, and any material obvious to the person skilled in the art can be applied as the material of the insulation substrate 24. Also, a reinforcing substrate can be used in order to increase mechanical strength and minimize the effects of temperature. A reinforcing substrate obvious to the person skilled in the art, such as paper, fiber glass, and nonwoven glass fabric, etc., may be used as the reinforcing substrate. An insulating material obvious to the person skilled in the art, such as epoxy, polyimide, fluoric resin, and PPO resin, etc., may be used as the material of the insulation substrate 24.

After aligning the insulation substrate 24 and the imprinting mold 26, the insulation substrate 24 and the imprinting mold 26 may be compressed together to imprint the raised pattern 25 into the insulation substrate 24. In this case, a pair of pressing plates can be used for compressing the imprinting mold 26 and the insulation substrate 24.

That is, the insulation substrate 24 and the imprinting mold 26 may be loaded onto a first pressing plate and aligned, and a second pressing plate may be stacked on top, and the first pressing plate and the second pressing may be compressed together so that the raised pattern 25 formed in the imprinting mold 26 may be imprinted into the insulation substrate 24.

A material having sufficient strength and thickness may be used for the pressing plates, in order to apply a uniform pressure distribution over the imprinting mold 26 and the insulation substrate 24.

A press may be used for the compression in the method for compressing the first pressing plate and the second pressing plate, but a heat-compression method of applying heat while pressing may also be advantageous. This is so that the raised pattern 25 of the imprinting mold 26 may be impressed in the insulation substrate 24 easily, after a temperature higher than glass transition temperature is applied to lower the viscosity of the insulation substrate 24. Moreover, when applying the heat-pressing, it may be desirable to perform the compressing in a vacuum chamber while applying heat. A reason for pressurizing the inside of the vacuum chamber is to form a layer of air between the insulation substrate 24 and the imprinting mold 26 to prevent the occurrence of defects in the intaglio pattern formed in the insulation substrate 24. Compression by means of a press may be used as the method for applying pressure on the pressing plate. It is also possible to apply pressure using liquid or high-pressure gas.

Besides this embodiment, align marks 30 may be formed in a first pressing plate, with the imprinting mold 26 and the insulation substrate 24 having align holes perforated in correspondence with the align mark 30, so that the imprinting mold 26 and the insulation substrate 24 may be aligned by perceiving the align marks 30 formed in the first pressing plate through the align holes. Finally, a second pressing plate may be loaded, and the first pressing plate and the second pressing plate may be compressed together, to form the intaglio pattern in the insulation substrate 24.

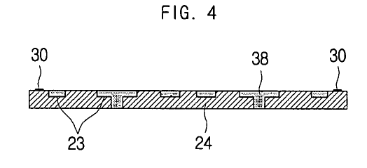

FIG. 4 is a side-elevational view illustrating a substrate in which a printed circuit pattern is formed according to an embodiment of the present invention. Referring to FIG. 4, an insulation substrate 24, align marks 30, an intaglio pattern 23, and conductive material 38 are illustrated.

As described in the above, after the imprinting mold and the insulation substrate 24 are loaded and pressed with a predetermined pressure and temperature, the imprinting mold may be separated from the insulation substrate 24, and the intaglio pattern 23 corresponding to the raised pattern of the imprinting mold may be formed in the insulation substrate 24. The intaglio pattern 23 formed in this insulation substrate 24 is where the circuit pattern, including via holes, may be formed, and it may be filled with conductive material 38 in order to form the circuit pattern in the insulation substrate 24.

A method for filling the conductive material 38 may be applied that is obvious to the person skilled in the art, which includes plating, such as by electroless plating and/or electroplating, filling with conductive paste, filling with conductive ink by inkjet printing, and filling with conductive polymers, etc. A conductive material 38 obvious to the person skilled in the art may be used as the conductive material 38 filled into the intaglio pattern 23 of the insulation substrate 24, including aluminum (Al), silver (Ag), copper (Cu), and chrome (Cr), etc.

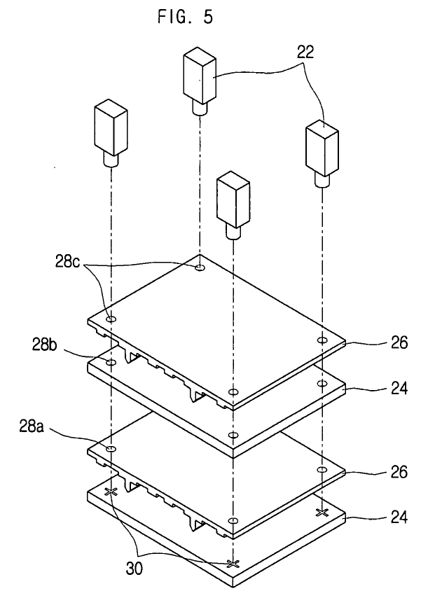

FIG. 5 is a perspective view illustrating a method for manufacturing multiple printed circuit boards according to an embodiment of the present invention. Referring to FIG. 5, cameras 22, an insulation substrate 24, an imprinting mold 26, first align holes 28a, second align holes 28b, third align holes 28c, and align marks 30 are illustrated.

In this embodiment, in order to form similar or dissimilar intaglio patterns on a plurality of insulation substrates 24 at the same time, an insulation substrate 24 having align marks 30 and an imprinting mold 26 having first align holes 28a corresponding to the align marks 30 may be loaded. Then, the insulation substrate 24 and the imprinting mold 26 may be aligned by perceiving the align marks 30 through the first align holes 28a. Before the insulation substrate 24 and the imprinting mold 26 are compressed to form an intaglio pattern corresponding to the raised pattern, another insulation substrate 24 or another imprinting mold 26 having second align holes 28b in correspondence with the align marks 30 can be loaded and aligned by perceiving the align marks 30 through the second holes 28b.

That is, once there are align marks formed as a basis for alignment, henceforth, it is possible to align a plurality of insulation substrates 24 and corresponding imprinting molds 26 by repeatedly loading and aligning the insulation substrate 24 or imprinting mold 26 having align holes that correspond with the align marks 30, by perceiving the align marks 30 through the align holes 28c. In this case, the insulation substrate 24 having second align holes 28b may be loaded and aligned, and then the imprinting mold 26 having third align holes 28c may be loaded onto the insulation substrate 24 such that the raised pattern of the imprinting mold 26 faces the insulation substrate 24. Conversely, the imprinting mold 26 having second align holes 28b may be loaded and aligned, and then, the insulation mold 24 having third align holes 28c may be loaded and aligned onto the imprinting mold 26.

Other imprinting molds 26 or other insulation substrates 24 may be loaded repeatedly as in the above process, whereby a plurality of insulation substrates 24 having the intaglio patterns can be produced by one instance of pressing.

While in this embodiment only two unit insulation substrates 24 are loaded, it is apparent that a plurality of unit insulation substrates 24 having the intaglio patterns formed can be produced at the same time by loading and compressing two or more unit insulation substrates 24 and unit imprinting molds 26.

The raised pattern formed in a plurality of imprinting molds 26 may be the same or may be different.

After a plurality of unit imprinting molds 26 and unit insulation substrates 24 are loaded and aligned, the plurality of unit insulation substrates 24 and unit imprinting molds 26 may be compressed at the same time, whereby a plurality of unit insulation substrates 24 can be produced in which intaglio patterns are formed.

While in this embodiment the method for loading a plurality of the unit insulation substrates 24 and unit imprinting molds 26 involve first loading the unit insulation substrates 24 and then the unit imprinting molds 26 onto the unit insulation substrates 24 such that the raised patterns of the unit imprinting molds 26 face the corresponding unit insulation substrates 24, in some cases, it is possible to first stack the imprinting molds 26 such that the raised patterns of the imprinting molds 26 face the insulation substrates 24 and then stack the insulation substrates 24 onto the imprinting molds 26. That is, when producing a plurality of insulation substrates 24, it does not matter in which order the unit imprinting molds 26 and the unit insulation substrates 24 are loaded, as long as they are arranged such that the raised pattern of a unit imprinting mold 26 and the surface of a unit insulation substrate 24, in which to form the intaglio pattern, face each other in a pair. This makes it possible to produce a plurality of unit insulation substrates 24 having intaglio patterns formed therein, with just one operation of compressing.

Besides this embodiment, the insulation substrate 24 may be loaded, an imprinting mold 26 may be loaded and aligned in which the raised pattern is formed on both sides, and then another insulation substrate 24 may be loaded and aligned and compressed, to produce two insulation substrates 24 in which intaglio patterns are formed at the same time in one set of one imprinting mold 26 and two insulation substrates 24.

After a plurality of the unit imprinting molds 26 and the unit insulation substrates 24 are loaded and compressed, the unit imprinting mold 26 and the unit insulation substrate 24 may be separated in reverse order of loading, with the intaglio pattern 23 corresponding to the raised patterns of the imprinting molds 26 formed in each of the unit insulation substrates 24. The intaglio patterns 23 formed in these unit insulation substrates 24 are where the circuit patterns including via holes may be formed, and they may be filled with conductive material, in order to form the circuit patterns on the insulation substrates 24.

A method for filling the conductive material may be applied that is obvious to the person skilled in the art, including plating by electroless plating and/or electroplating, filling with conductive paste, filling with conductive ink by inkjet printing, and filling with conductive polymers, etc.

A conductive material obvious to the person skilled in the art, including aluminum (Al), silver (Ag), copper (Cu), and chrome (Cr), etc., may be used as the conductive material filled into the intaglio patterns of the insulation substrates 24.

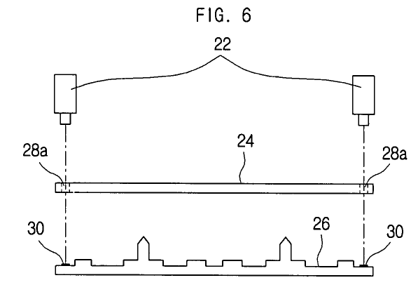

FIG. 6 is a side-elevational view illustrating a method for manufacturing a printed circuit board according to another embodiment of the present invention. Referring to FIG. 6, cameras 22, an insulation substrate 24, an imprinting mold 26, first align holes 28a, and align marks 30 are illustrated.

In this embodiment, a circuit pattern may be formed with the align marks 30 formed on the imprinting mold 26 instead of the insulation substrate 24.

The align mark 30 may be formed on a dummy area of the imprinting mold 26, and the imprinting mold 26 may be loaded such that the surface of the imprinting mold 26 having a raised pattern faces the surface of the insulation substrate 24 in which to form the intaglio pattern. The insulation substrate 24 having a first align hole 28a in correspondence with the align mark 30, may be loaded such that the surface of the insulation substrate 24 in which to form the intaglio pattern faces the surface of an imprinting mold 26 having the raised pattern.

Afterwards, the insulation substrate 24 and the imprinting mold 26 may be aligned by perceiving the align mark formed in the imprinting mold 26 through the first align hole 28a formed in the insulation substrate 24 using a certain optical device (e.g. a camera 22, etc).

As described in the above, a plurality of align marks 30 may be formed, with the size of the align holes 28a formed smaller, in order to align the insulation substrate 24 and the imprinting mold 26 with greater accuracy.

After aligning the insulation substrate 24 and the imprinting mold 26, the insulation substrate 24 and the imprinting mold 26 may be compressed together to imprint the raised pattern into the insulation substrate 24.

While in this embodiment, the imprinting mold 26 is loaded first and the insulation substrate 26 is loaded onto the upper part of the imprinting mold 26 afterwards such that the surface of the imprinting mold 26 having the raised pattern faces the surface of the insulation substrate 24 to form an intaglio pattern, the loading order of the insulation substrate 24 and the imprinting mold 26 is not of great importance, as long as the imprinting mold 26 and insulation substrate 24 are aligned in a pair such that a surface of the imprinting mold 26 having the raised pattern faces a surface of the insulation substrate in which to form the intaglio pattern.

Beside this embodiment, an align mark 30 may be formed in a first pressing plate, and an imprinting mold 26 or an insulation substrate 24 having an align hole perforated in correspondence with the align mark may be aligned by perceiving the align mark formed in the first pressing plate through the align hole. Finally, a second pressing plate may be loaded, and the first pressing plate and the second pressing plate may be compressed together, to form an intaglio pattern in the insulation substrate.

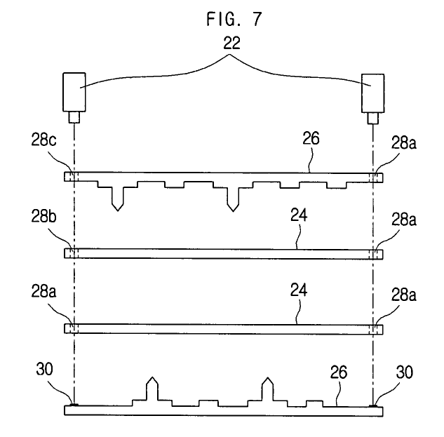

FIG. 7 is a side-elevational view illustrating a method for manufacturing multiple printed circuit boards according to another embodiment of the present invention. Referring to FIG. 7, cameras 22, an insulation substrate 24, an imprinting mold 26, first align holes 28a, second align holes 28b, third align holes 28c, and align marks 30 are illustrated.

In this embodiment, in order to form similar or dissimilar intaglio patterns on a plurality of insulation substrates 24 at the same time, an imprinting mold 26 having an align mark 30 and an insulation substrates 24 having a first align hole 28a corresponding the align mark 30 may be loaded. Then, the insulation substrate 24 and the imprinting mold 26 may be aligned by perceiving the align mark 30 through the first align hole 28a. Before the insulation substrate 24 and the imprinting mold 26 are compressed to form an intaglio pattern corresponding the raised pattern, another insulation substrate 24 or another imprinting mold 26 having a second align hole 28b in correspondence with the align mark 30 formed in the imprinting mold 26 may be loaded and aligned, by perceiving the align mark 30 through the second hole 28b. In this case, the imprinting mold 26 or the insulation substrate 24 may be aligned, every time the imprinting mold 26 or the insulation substrate 24 is loaded one by one, by perceiving the align mark 30 through the second align hole 28b.

That is, once there is an align mark formed as a basis for alignment, henceforth, it is possible to align a plurality of the insulation substrates 24 and corresponding imprinting molds 26 by repeatedly loading and aligning the insulation substrate 24 or imprinting mold 26 having an align hole in correspondence with the align mark 30, by perceiving the align mark 30 through the align hole. In this case, the insulation substrate 24 having the second align hole 28b may be loaded and aligned, and then the imprinting mold 26 having a third align hole 28c may be loaded onto the insulation substrate 24 such that the raised pattern of the imprinting mold 26 faces the insulation substrate 24. Conversely, the imprinting mold 26 having the second align hole 28b may be loaded and aligned, and then, the insulation mold 24 having the third align hole 28c may be loaded and aligned onto the imprinting mold 26.

Other imprinting molds 26 and other insulation substrates 24 may be loaded repeatedly as in the above process, whereby a plurality of insulation substrates 24 having the intaglio patterns can be produced by one instance of pressing.

While in this embodiment only two unit insulation substrates 24 are loaded, it is apparent that a plurality of unit insulation substrates 24 having the intaglio patterns formed can be produced at the same time by loading and compressing two or more unit insulation substrates 24 and unit imprinting molds 26.

The raised pattern formed in a plurality of imprinting molds 26 may be the same or may be different.

After a plurality of unit imprinting molds 26 and unit insulation substrate 24 are loaded and aligned, the plurality of unit insulation substrates 24 and unit imprinting molds 26 may be compressed at the same time, whereby a plurality of unit insulation substrates 24 can be produced in which intaglio patterns are formed.

While in this embodiment the method for loading a plurality of the unit insulation substrates 24 and unit imprinting molds 26 involve first loading the unit insulation substrates 24 and then the unit imprinting molds 26 onto the unit insulation substrates 24 such that the raised patterns of the unit imprinting molds 26 face the corresponding unit insulation substrates 24, in some cases, it is possible to first stack the imprinting molds 26 such that the raised patterns of the imprinting molds 26 face the insulation substrates 24 and then to stack the insulation substrates 24 onto the imprinting molds 26. That is, when producing a plurality of insulation substrates 24, it does not matter in which order the unit imprinting molds 26 and the unit insulation substrates 24 are loaded, as long as they are arranged such that the raised pattern of a unit imprinting mold 26 and the surface of a unit insulation substrate 24, in which to form the intaglio pattern, face each other in a pair. This makes it possible to produce a plurality of unit insulation substrates having intaglio patterns formed therein, with just one operation of compressing.

As described in the above, after a plurality of the unit imprinting molds 26 and the unit insulation substrates 24 are loaded and compressed, the unit imprinting molds 26 and the unit insulation substrates 24 may be separated in reverse order of loading, with the intaglio pattern 23 corresponding to the raised patterns of the imprinting molds 26 formed in each of the unit insulation substrates 24. The intaglio patterns 23 formed in these unit insulation substrates 24 are where the circuit patterns including via holes may be formed, and they may be charged with conductive material in order to form the circuit patterns on the insulation substrates 24.

A method for filling the conductive material may be applied that is obvious to the person skilled in the art, including plating by electroless plating and/or electroplating, filling with conductive paste, filling with conductive ink by inkjet printing, and filling with conductive polymers, etc.

A conductive material obvious to the person skilled in the art may be used as the conductive material filled into the intaglio patterns of the insulation substrates 24, including aluminum (Al), silver (Ag), copper (Cu), and chrome (Cr), etc.

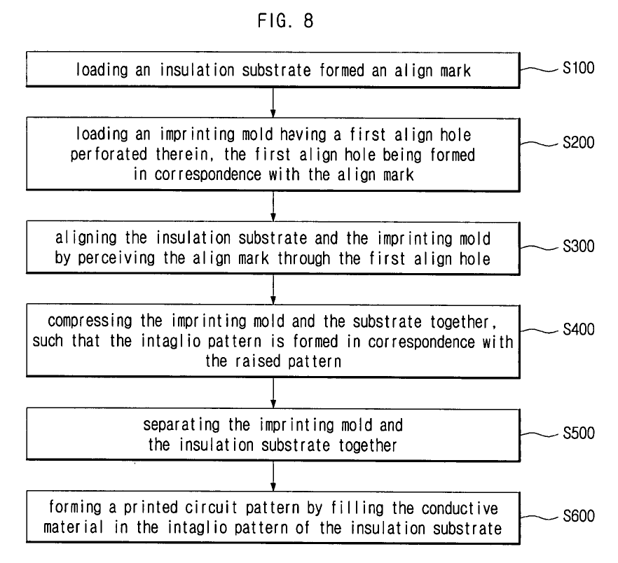

FIG. 8 is a flowchart illustrating a method for manufacturing a printed circuit board according to an embodiment of the present invention. Referring to FIG. 8, as part of a method for manufacturing a printed circuit board in which a printed circuit pattern is formed by filling a conductive material into an intaglio pattern formed in an insulation substrate by imprinting a raised pattern formed in an imprinting mold in correspondence with circuit pattern onto the insulation substrate, in operation S100, an align mark 30 may be formed in a dummy area of an insulation substrate, and the insulation substrate may be loaded such that the surface of the insulation substrate in which to form the intaglio pattern faces the surface of the imprinting mold having a raised pattern.

A plurality of align marks may be formed, in order to align the insulation substrate and the imprinting mold with greater accuracy. Therefore, a plurality of align holes may be perforated in correspondence with the plurality of align marks. The smaller the size of the align hole, within the scope that allows perceiving the align mark through the align hole, the higher the exactitude of alignment. For example, in a PCB manufacturing process, a plurality of identical unit PCB's may be processed in one substrate at the same time, and then cut into unit PCB's afterwards. In the case of imprint processing a plurality of identical unit PCB's in an insulation substrate to form circuit patterns, the insulation substrate may be relatively large, so that the exactitude of alignment may be increased by forming a plurality of align marks and align holes.

A thermoplastic resin may be used as the material of the insulation substrate. However, the material of the insulation substrate is not limited to thermoplastic resins, and any material obvious to the person skilled in the art can be applied as the material of the insulation substrate. Also, a reinforcing substrate can be used, in order to increase mechanical strength and minimize the effects of temperature. A reinforcing substrate obvious to the person skilled in the art, such as paper, fiber glass, and nonwoven glass fabric, etc., may be used as the reinforcing substrate. An insulating material obvious to the person skilled in the art, such as epoxy, polyimide, fluoric resin, and PPO resin, etc., may be used as the material of the insulation substrate.

In operation S200, an imprinting mold may be loaded onto the insulation substrate having a first align hole loaded in the previous operation, such that the surface of the insulation substrate in which to form the intaglio pattern faces the surface of an imprinting mold having a raised pattern.

While in this embodiment, the insulation substrate is loaded first and the imprinting mold is loaded onto the upper part of the insulation substrate afterwards such that a surface of the imprinting mold having the raised pattern faces the insulation substrate, in some cases, it is possible to first load the imprinting mold, and load the insulation substrate onto the imprinting mold such that the surface of the imprinting mold having the raised pattern faces the insulation substrate. That is, as long as the imprinting mold and insulation substrate are aligned in a pair such that a surface of the imprinting mold having the raised pattern faces a surface of the insulation substrate to form the intaglio pattern, the loading order of the insulation substrate and the imprinting mold is not of great importance.

Metals such as iron (Fe), nickel (Ni), platinum (Pt), and chrome (Cr), etc., or diamond, quartz, or polymers, which are relatively strong in comparison to the insulation substrate 24, may be used as the material of the imprinting mold 26. Also, the raised pattern 25 formed in the imprinting mold 26 is not limited to certain shapes, such as square shapes, V shapes, and U shapes, etc.

After this step, another insulation substrate or another imprinting mold having a second align hole in correspondence with the align mark formed in the insulation substrate can be loaded and aligned by perceiving the align mark through the second hole. In this case, the imprinting mold or the insulation substrate may be aligned by perceiving the align mark through the second align hole, every time the imprinting mold or the insulation substrate is loaded one by one. That is, once there is an align mark formed as a basis for alignment, henceforth, it is possible to align a plurality of the insulation substrates and corresponding imprinting molds by repeatedly loading and aligning an insulation substrate or an imprinting mold having an align hole in correspondence with the align mark, by perceiving the align mark through the align hole.

Other imprinting molds and other insulation substrates may be loaded repeatedly as in the above process, whereby a plurality of insulation substrates 24 having the intaglio patterns can be produced by on instance of pressing. The raised patterns formed in the plurality of imprinting molds may be the same or may be different.

After a plurality of unit imprinting molds and unit insulation substrates are loaded and aligned, the plurality of unit insulation substrates and unit imprinting molds may be compressed at the same time, whereby a plurality of unit insulation substrates can be produced in which intaglio patterns are formed.

In operation S300, the insulation substrate and the imprinting mold may be aligned by perceiving the align mark through the first align hole using a certain optical device (e.g. a camera, etc).

In operation S400, the insulation substrate and the imprinting mold may be compressed together to imprint the raised pattern into the insulation substrate. A pair of pressing plates can be used for compressing the insulation substrate and the imprinting mold. That is, the insulation substrate and the imprinting mold may be loaded onto a first pressing plate and aligned, and a second pressing plate may be stacked on top, at which the first pressing plate and the second pressing may be compressed together such that the raised pattern formed in the imprinting mold may be imprinted into the insulation substrate.

A material having sufficient strength and thickness may be used for the pressing plates, in order to apply a uniform pressure distribution over the imprinting mold and the insulation substrate.

A press may be used for the compression in the method for compressing the first pressing plate and the second pressing plate together, but a heat-compression method of applying heat while pressing may also be advantageous. This is so that the raised pattern of the imprinting mold may be impressed in the insulation substrate easily, after a temperature higher than glass transition temperature is applied to lower the viscosity of the insulation substrate. Moreover, when applying the heat-pressing, it may be desirable to perform the compressing in a vacuum chamber while applying heat. A reason for pressurizing the inside of the vacuum chamber is to form a layer of air between the insulation substrate and the imprinting mold to prevent the occurrence of defects in the intaglio pattern formed in the insulation substrate. Compression by means of a press may be used as the method for applying pressure on the pressing plate. However, it is also possible to apply pressure using liquid or high-pressure gas.

Besides this embodiment, an align mark may be formed in a first pressing plate, with the imprinting mold and the insulation substrate having an align hole perforated in correspondence with the align mark, so that the imprinting mold and the insulation substrate may be aligned by perceiving the align mark formed in the first pressing plate through the align hole. Finally, a second pressing plate may be loaded, and the first pressing plate and the second pressing plate may be compressed together, to form the intaglio pattern in the insulation substrate.

In operation S500, after the raised pattern of the imprinting mold is impressed to a predetermined depth, the imprinting mold and the insulation substrate may be separated. An intaglio pattern may be formed in the separated insulation substrate in correspondence with the raised pattern of the imprinting mold.

The intaglio pattern formed in this insulation substrate is where the circuit pattern, including via holes, may be formed, and in operation S600, the intaglio pattern may be filled with conductive material in order to form the circuit pattern in the insulation substrate. A method for filling the conductive material obvious to the person skilled in the art may be applied, which includes plating by electroless plating and/or electroplating, filling with conductive paste, filling with conductive ink by inkjet printing, and filling with conductive polymers, etc. A conductive material obvious to the person skilled in the art may be used as the conductive material filled into the intaglio pattern of the insulation substrate, including aluminum (Al), silver (Ag), copper (Cu), and chrome (Cr), etc.

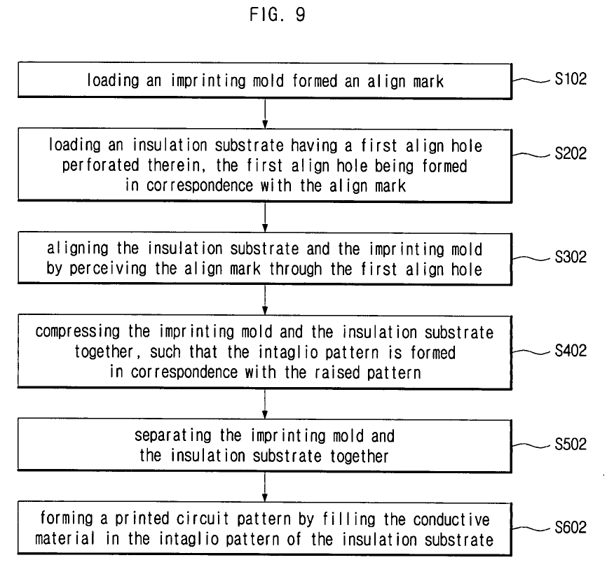

FIG. 9 is a flowchart illustrating a method for manufacturing a printed circuit board according to another embodiment of the present invention. Referring to FIG. 9, as a method for manufacturing a printed circuit board in which a printed circuit pattern is formed by filling a conductive material into an intaglio pattern formed in an insulation substrate by imprinting a raised pattern formed in an imprinting mold in correspondence with a circuit pattern onto the insulation substrate, in this embodiment, the circuit pattern may be formed by forming the align mark on the imprinting mold instead of the insulation substrate.

In operation S102, an align mark may be formed in a dummy area of an imprinting mold, where the imprinting mold may be loaded such that a surface of the imprinting mold having a raised pattern faces the surface of the insulation substrate in which to form the intaglio pattern.

In operation S202, the insulation substrate having a first align hole in correspondence with the align mark of the imprinting mold loaded in the previous operation, may be loaded such that a surface of the insulation substrate in which to form the intaglio pattern faces a surface of the imprinting mold having the raised pattern.

While in this embodiment, an imprinting mold is loaded first and the insulation substrate is loaded onto the imprinting mold afterwards such that a surface of the imprinting mold having the raised pattern faces the insulation substrate, in some cases, it is possible to first load the insulation substrate, and then load the imprinting mold onto the insulation substrate. That is, as long as the imprinting mold and insulation substrate are aligned in a pair such that a surface of the imprinting mold having the raised pattern faces a surface of the insulation substrate in which to form the intaglio pattern, the loading order of the insulation substrate and the imprinting mold is not of great importance.

After this step, another insulation substrate or another imprinting mold having a second align hole in correspondence with the align mark formed in the imprinting mold can be loaded and aligned by perceiving the align mark through the second hole. That is, once there is an align mark formed as a basis for alignment, henceforth, it is possible to align a plurality of the insulation substrates and corresponding imprinting molds by repeatedly loading and aligning an insulation substrate or an imprinting mold having an align hole in correspondence with the align mark, by perceiving the align mark through the align hole.

Other imprinting mold and other insulation substrate may be loaded repeatedly as in the above process, whereby a plurality of insulation substrates 24 having the intaglio patterns can be produced by on instance of pressing. The raised pattern formed in the plurality of imprinting molds may be the same or may be different.

After a plurality of unit imprinting molds and unit insulation substrate are loaded and aligned, the plurality of unit insulation substrates and unit imprinting molds may be compressed at the same time, whereby a plurality of unit insulation substrates can be produced in which intaglio patterns are formed.

In operation S302, the insulation substrate and the imprinting mold may be aligned by perceiving the align mark through the first align hole using a certain optical device (e.g. cameras, etc).

In operation S402, the insulation substrate and the imprinting mold may be compressed together to imprint the raised pattern into the insulation substrate. A pair of pressing plates can be used for compressing the insulation substrate and the imprinting mold, as described in the above.

Besides this embodiment, an align mark may be formed in a first pressing plate, and an imprinting mold or an insulation substrate having an align hole perforated in correspondence with the align mark may be aligned by perceiving the align mark formed in the first pressing plate through the align hole. Finally, a second pressing plate may be loaded and to compress the first pressing plate and the second pressing plate together, so that an intaglio pattern may be formed in the insulation substrate.

In operation S502, after the raised pattern of the imprinting mold is impressed to a predetermined depth, the imprinting mold and the insulation substrate may be separated. An intaglio pattern may be formed in the separated insulation substrate in correspondence with the raised pattern of the imprinting mold.

The intaglio pattern formed in this insulation substrate is where the circuit pattern, including via holes, may be formed, and in operation S602, the intaglio pattern may be filled with conductive material, to form the circuit pattern in the insulation substrate.

With certain aspects of the invention as set forth above, it is possible to use existing optical systems, for an imprinting process involving an imprinting mold having a raised pattern and an insulation substrate having an intaglio pattern formed in correspondence with the raised pattern, in aligning an opaque imprinting mold and an insulation substrate, without installing expensive alignment instruments, and to manufacture several insulation substrates having circuit patterns by sequentially loading and aligning several imprinting molds and insulation substrates and compressing simultaneously.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing a printed circuit board by imprinting a raised pattern formed in an imprinting mold in correspondence with a circuit pattern onto an insulation substrate to form an intaglio pattern, and filling a conductive material into the intaglio pattern formed in the insulation substrate to form a printed circuit pattern, the method comprising:
loading an insulation substrate having an align mark formed thereon;
loading an imprinting mold having a first align hole perforated therein, the first align hole being formed in correspondence with the align mark;
aligning the insulation substrate and the imprinting mold by perceiving the align mark through the first align hole; and
compressing the imprinting mold and the insulation substrate together, such that the intaglio pattern is formed in correspondence with the raised pattern.

2. The method of claim 1, further comprising, between the aligning and the compressing:
loading an insulation substrate or an imprinting mold having a second align mark perforated therein, the second align hole being formed in correspondence with the align mark; and
aligning the insulation substrate or the imprinting mold by perceiving the align mark through the second align hole.

3. The method of claim 1, wherein the align mark is formed in a plurality.

4. The method of claim 1, further comprising, after the compressing:
separating the imprinting mold and the insulation substrate; and
filling the intaglio pattern with conductive material to form a printed circuit pattern.

5. A method for manufacturing a printed circuit board by imprinting a raised pattern formed in an imprinting mold in correspondence with a circuit pattern onto an insulation substrate to form an intaglio pattern, and filling a conductive material into the intaglio pattern formed in the insulation substrate to form a printed circuit pattern, the method comprising:
loading an imprinting mold having an align mark formed thereon;
loading an insulation substrate having a first align hole perforated therein, the first align hole being formed in correspondence with the align mark;
aligning the insulation substrate and the imprinting mold by perceiving the align mark through the first align hole; and
compressing the imprinting mold and the insulation substrate together, such that the intaglio pattern is formed in correspondence with the raised pattern.

6. The method of claim 5, further comprising, after the compressing:
separating the imprinting mold and the insulation substrate; and
filling the intaglio pattern with conductive material to form a printed circuit pattern.
